(19) United States
(12) Patent Application Publication
(10) Pub. No.: US 2023/0204684 A1
(43) Pub. Date: Jun. 29, 2023

(54) COMPUTER-AIDED TESTER FOR CHECKING CONTINUITY OF CIRCUIT

(71) Applicants: SHANGHAI BRAINPAW ELECTRONIC TECHNOLOGY CO., LTD., Shanghai (CN); SHANGHAI YULING THERMAL CONTROL TECHNOLOGY CO., LTD., Shanghai (CN)

(72) Inventor: Fuhui CHEN, Shanghai (CN)

(73) Assignees: SHANGHAI BRAINPAW ELECTRONIC TECHNOLOGY CO., LTD., Shanghai (CN); SHANGHAI YULING THERMAL CONTROL TECHNOLOGY CO., LTD., Shanghai (CN)

(21) Appl. No.: 17/916,073

(22) PCT Filed: Mar. 23, 2021
(86) PCT No.: PCT/CN2021/082419

§ 371 Date: Sep. 30, 2022

(30) Foreign Application Priority Data
Apr. 7, 2020 (CN) 202020495406.2

(51) Int. Cl. G01R 31/54

(52) U.S. Cl. CPC G01R 31/54

(57) ABSTRACT

A computer-aided tester for checking a continuity of a circuit includes a computer and two or more handheld inspection parts. Each of the two handheld inspection parts is provided with a probe and an illuminating lamp, and the probe and the illuminating lamp are directly connected to the computer through a circuit. The computer-aided tester for checking the continuity of the circuit improves the efficiency and reliability of wiring quality inspection by using a computer-aided technology and method.

### CROSS REFERENCE TO THE RELATED APPLICATIONS

This application is the national phase entry of International Application No. PCT/CN2021/082419, filed on Mar. 23, 2021, which is based upon and claims priority to Chinese Patent Application No. 202020495406.2, filed on Apr. 07, 2020, the entire contents of which are incorporated herein by reference.

### TECHNICAL FIELD

The present invention belongs to the technical field of electrotechnology, and particularly to a computer-aided tester for checking a continuity of a circuit.

### BACKGROUND

In all fields where electrotechnology is used, such as information technology (IT), power transmission and distribution, and industrial automation, the first step in system integration is wiring according to design. After the completion of the wiring and before the power-on debugging of the system, it is necessary to inspect the quality of the wiring for the safety of electrical equipment and personnel.

The current common method to inspect the quality of wiring is the following: a quality inspector, according to the wiring table, uses a multimeter to check whether two terminals that should be connected are really connected, and then records and reports the inspection results manually. Since the quality inspector has to do the inspection and record the inspection result while looking at the wiring table, the efficiency is low. Moreover, the result of each inspection depends on the working attitude of the quality inspector, and missing inspection and wrong inspection are inevitable, so the inspection result is insufficiently reliable.

With increasingly improved technologies of 1T and artificial intelligence (AI) hardware and software, it is required to provide a wiring inspection method with higher accuracy and reliability.

### SUMMARY

The objective of the present invention is to provide a computer-aided tester for checking a continuity of a circuit. The computer-aided tester includes: a computer and two or more handheld inspection parts. Each of the handheld inspection parts is provided with a probe and an illuminating lamp, and the probe and the illuminating lamp are directly connected to the computer through a circuit.

The computer issues an inspection instruction according to an inspection solution, detects the continuity of a to-be-checked circuit between the two or more probes, and records an inspection result.

The computer controls the illuminating lamp according to the inspection solution and the inspection result.

In the computer-aided tester for checking the continuity of the circuit disclosed by the present invention, the computer issues the inspection instruction according to the inspection solution, and turns on the illuminating lamp while issuing the inspection instruction to help the quality inspector find the terminals of the to-be-checked circuit. The quality inspector presses the probes on the handheld inspection parts on the two terminals of the to-be-checked circuit according to the instruction. The computer checks and records the continuity of the to-be-checked circuit between the two or more probes. After the inspection is completed, the computer turns off the illuminating lamp and notifies the quality inspector that the current inspection instruction has been completed.

The computer-aided tester for checking the continuity of the circuit of the present invention has the following advantages: depending on the latest computer technology, the instruction for checking the continuity of the circuit is sent by the computer in the form of multimedia, and the inspection result is recorded and reported by the computer, thus simplifying the manual quality inspection, reducing the labor intensity of quality inspector, and improving the efficiency and accuracy of circuit continuity inspection.

### BRIEF DESCRIPTION OF THE DRAWINGS

FIG. 1 is a schematic diagram showing the structure of a computer-aided tester for checking a continuity of a circuit according to the present invention.

FIG. 2 is a work flow chart of a computer-aided tester for checking a continuity of a circuit according to the present invention.

Reference numerals: 1-computer; 2-illuminating lamp; 3-handheld inspection part; 4-probe

### DETAILED DESCRIPTION OF THE EMBODIMENTS

The present invention discloses a computer-aided tester for checking a continuity of a circuit. Taking one of a variety of embodiments as an example, the technology disclosed by the present invention is described in detail below:

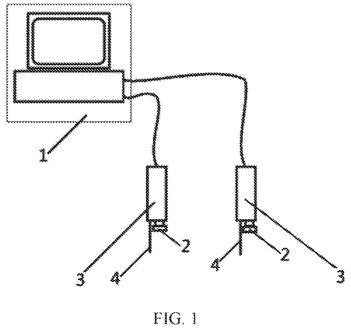

FIG. 1 is a schematic diagram of the structure of the computer-aided tester for checking the continuity of the circuit disclosed by the present invention. The computer-aided tester includes one computer 1 and two handheld inspection parts 3. Each of the two handheld inspection parts 3 is provided with one probe 4 and one illuminating lamp 2, and each of the probe 4 and the illuminating lamp 2 is connected to the computer 1 through a circuit (the circuit connection may be: USB connection or cable connection or WIFI connection). The computer 1 is configured to check the continuity of inspected to-be-checked circuit between the two probes 4 and control the illuminating lamp 2. to be turned on and turned off.

In practical work, it is often necessary to connect a plurality of handheld inspection parts 3 based on the actual situation of the to-be-checked circuit, so that the continuity of the to-be-checked circuits between a plurality of probes 4 can be checked simultaneously.

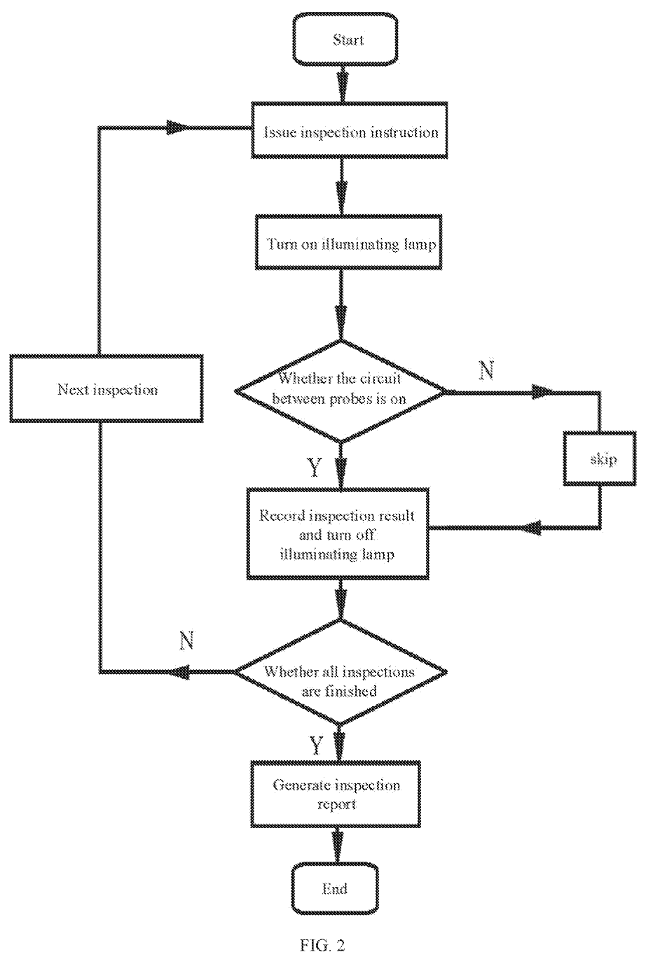

FIG. 2 shows a work flow of the computer-aided tester for checking the continuity of the circuit disclosed by the present invention. According to an inspection solution, the computer 1 issues an inspection instruction and turns on the illuminating lamp 2. With the assist of the illuminating lamp 2, a quality inspector presses the probes 4 on two terminals of the to-be-checked circuit according to the inspection instruction. If the to-be-checked circuit is on, the computer 1 records that the inspection result of the to-be-checked circuit is on and turns off the illuminating lamp 2. If the to-be-checked circuit is off, the quality inspector operates the computer to skip the current inspection instruction, and the computer 1 records that the inspection result of the to-be-checked circuit is off and turns off the illuminating lamp 2. According to the inspection solution, the computer 1 circularly checks the continuity of all circuits until completion, and finally generates an inspection report.

Specifically, according to a design scheme, the circuit connection diagram or table is first entered into the computer 1. At the beginning of the inspection, according to the entered circuit connection diagram or table, the computer 1 sends out the inspection instructions containing information of the two terminals and wire number of a to-be-checked circuit one by one in a multimedia manner and turns on the illuminating lamp 2 on each of the handheld inspection parts 3. According to the inspection instruction, the quality inspector contacts the probes 4 on the handheld inspection parts 3 with the two terminals of the to-be-checked circuit. If the to-be-checked circuit is determined to be on, the computer 1 turns off the illuminating lamp 2 and records the inspection result. If the to-be-checked circuit is determined to be off, the quality inspector gives a skip instruction to the computer 1, and then the computer 1 turns off the illuminating lamp 2 and records the inspection result. The operations are circularly performed until all the circuits are checked, and the computer 1 generates the final inspection report.

What is claimed is:

1. A computer-aided tester for checking a continuity of a circuit, comprising a computer and at least two handheld inspection parts, wherein each of the at least two handheld inspection parts is provided with a probe and an illuminating lamp, and the probe and the illuminating lamp are directly connected to the computer through a circuit.
